(19) United States
(12) Patent Application Publication
(10) Pub. No.: US 2012/0073640 A1
(43) Pub. Date: Mar. 29, 2012

(54) PULSED PHOTOTHERMAL PHASE TRANSFORMATION CONTROL FOR TITANIUM OXIDE STRUCTURES AND REVERSIBLE BANDGAP SHIFT FOR SOLAR ABSORPTION

(75) Inventors: Claus Daniel, Knoxville, TN (US); Constantinos Tsouris, Oak Ridge, TN (US); Nickolay V. Lavrik, Knoxville, TN (US); Panagiotis G. Datskos, Knoxville, TN (US); Ronald D. Ott, Knoxville, TN (US); Viviane Schwartz, Knoxville, TN (US); Adrian S. Sabau, Knoxville, TN (US)

(73) Assignee: UT-Battelle, LLC, Oak Ridge, TN (US)

(21) Appl. No.: 12/889,478

(22) Filed: Sep. 24, 2010

(51) Int. Cl. H01L 31/032; H01L 31/18

(52) U.S. Cl. 136/256; 438/93; 257/E31.026

(57) ABSTRACT

A method for bandgap shift and phase transformation for titania structures. The method can include providing a flexible substrate, depositing a titania film onto the substrate, and exposing the titania film to one or more pulses of infrared energy of sufficient energy density and for a sufficient time to crystallize the titania film to predominantly anatase crystalline phase. The flexible substrate can be formed from a polymeric material, and the method can achieve a bandgap shift from greater than 3.0 eV to approximately 2.4 eV. The method can also include forming a crystalline titania layer over a substrate and annealing the crystalline titania layer by applying pulsed thermal energy sufficient to modify the phase constitution of the crystalline titania layer. The source of pulsed thermal energy can include an infrared flashlamp or laser, and the resulting titania structure can be used with photovoltaic and photoelectrolysis systems.

This invention was made with government support under Contract No. DE-ACO5-000R22725 awarded by the U.S. Department of Energy. The government has certain rights in the invention.

### BACKGROUND OF THE INVENTION

The present invention relates to a method for fabricating titania (TiO₂) structures, and more particularly, a method for phase transformation and bandgap shift of titania structures on flexible substrates for solar absorption.

Photovoltaic devices involve the conversion of light into electricity. To effectively convert sunlight into electricity, photovoltaic devices include a semiconductor material having a “bandgap” matched to the solar spectrum at the earth's surface. When the energy of incident light is equal to that of a material's bandgap or greater, the material can absorb photons of solar energy sufficient to create electron-hole pairs, thereby creating an internal electric field. The internal electric field creates a buildup of voltage between two electrodes to provide a source of electrical power.

Photovoltaic devices also include a substrate for supporting the semiconductor material. Known substrates include ceramics such as quartz and soda lime glass. These materials are relatively resistant to high temperatures, but are inflexible and are not suited for large area production of photovoltaic devices. Where it is desirable to include a flexible substrate, a polymeric substrate is often utilized. Many polymeric substrates have a relatively low upper operating temperature (i.e., the temperature at which the material will degrade or decompose), and are normally not utilized in processes involving high heat.

Titania is desirable as a photovoltaic material because of its low water-solubility, high stability, and non-toxicity, and because it is highly suited as a photocatalyst in the conversion of water into hydrogen. Titania in the anatase phase normally has a bandgap of approximately 3.0-3.2 eV. To activate its photovoltaic properties, titania requires light of approximately 390 nm wavelength—corresponding to ultraviolet light. However, only a small percentage of solar energy received at the earth's surface is ultraviolet light, while about 45% of the solar energy received at the earth's surface is visible light, with much of the remaining light being infrared. To tailor the bandgap of titania to the visible spectrum where sunlight is relatively high in intensity, a “shifting” of the bandgap is desired.

There are at least three general methods for shifting the bandgap of a titania structure: subjecting the structure to stress, infusing the structure with dopants, and annealing the structure under high heat. However, each of these methods have inherent disadvantages, and none are particularly well suited for fabricating titania structures on polymeric substrates. Stress-induced bandgap shift can fracture the crystalline material and/or delaminate the titania with respect to an underlying substrate. Doping can involve highly toxic byproducts and added production costs not suitable for large area, high throughput production. Conventional heat anneal processes, such as calcination, can include exposure to temperatures well in excess of the maximum operating temperatures of flexible, polymeric substrates. Even where a thermally insulating layer is positioned between the flexible substrate and a titania deposit, conventional heat anneal processes can damage both the substrate and the substrate-titania interface.

Therefore, there remains a need for a low-cost method for manufacturing photovoltaic titania on flexible, large area substrates. In particular, there remains a need for an improved process for achieving bandgap shift and phase transformation of titania for solar absorption while leveraging the benefits of flexible titania structures materials across a wide range of applications.

### SUMMARY OF THE INVENTION

The aforementioned problems are overcome by the present invention which provides a photovoltaic device and a method for bandgap shift and/or phase transformation of a titania structure while having a minimal thermal impact on an underlying substrate. According to a first aspect of the present invention, the method includes directing energy of a sufficient intensity and for sufficient duration toward a surface of a titania structure to achieve bandgap shift and/or phase transformation without materially affecting the underlying substrate. In particular, the method can include directing one or more intense pulses of radiant energy or laser energy toward a superficial region of the titania structure opposite the substrate that are sufficient to produce a bandgap shift and/or a phase transformation without causing the substrate to exceed its upper operating temperature.

According to one embodiment of the invention, the method can include providing a flexible substrate, depositing a titania film onto the substrate, and exposing the titania film to one or more pulses of infrared energy of sufficient energy density to crystallize the titania film to predominantly anatase crystalline phase. The flexible substrate can be formed from a polymeric material, for example polyimide or polycarbonate. The flexible substrate can further include a conducting layer at least partially in contact with the titania film. The exposing step can include exposing the titania film to pulsed energy having a sufficient intensity and for a sufficient duration to achieve a band gap shift without having a material negative effect on the polymeric substrate. For example, the exposing step can include exposing the titania film to at least one pulse of primarily infrared radiation from an infrared flashlamp. The flashlamp can generate one or more pulses having a duration of approximately 100 ms. Alternatively, the exposing step can include exposing the titania film to multiple pulses of primarily infrared radiation from a laser. The laser can include an energy density of approximately 330 mJ/cm² and can generate pulses having a duration of approximately 2.5 ns and a periodicity of approximately 550 ns. Throughout the exposing step, the temperature of the substrate can remain at levels sufficient to limit or prevent damage to the substrate. For example, the temperature of the substrate can remain at levels sufficient to limit or prevent melting and/or warping of the polymeric substrate. The temperature of the substrate can remain below 400° C., optionally as low as 200° C. throughout the exposing step while achieving a bandgap shift from greater than 3.0 eV to between 2.0 eV and 3.0 eV, optionally approximately 2.4 eV.

According to another embodiment of the invention, the method can include forming a crystalline titania layer over a substrate and annealing the crystalline titania layer by applying pulsed thermal energy sufficient to modify the phase constitution of the crystalline titania layer without materially affecting an underlying substrate. The step of applying pulsed thermal energy can include providing a laser. In one embodiment, the laser can include an energy density of approximately 330 mJ/cm². The step of applying a pulsed thermal energy can alternatively include providing an infrared flashlamp. In one embodiment, the infrared flashlamp can include a power output of about 20,000 W/cm² or less. The substrate can be formed of a polymeric material, and can include a conducting layer disposed between the substrate and the titania layer. The pulsed thermal energy can be sufficient to achieve a phase transformation from rutile to anatase phase, or from anatase to rutile phase, without materially affecting the underlying polymeric substrate.

According to a second aspect of the present invention, a laminated article generally includes a flexible substrate and a titania layer supported by and optionally in contact with the substrate, with the titania layer being predominantly anatase crystalline phase. The flexible substrate can be formed of a polymeric material, and the titania layer can include a band gap between its valence band and its conduction band of approximately 2.4 eV. The laminated article can be formed with exposure to at least one pulse of energy from an infrared flashlamp or a laser, the pulse of energy being of a sufficient intensity and a sufficient duration to shift the bandgap to approximately 2.4 eV. In addition, the laminated article can include an optional conducting layer at least partially in contact with the titania layer.

A titania device formed according to the present invention is well suited to form part of a solid-state semiconductor solar cell, a dye-sensitized solar cell, or any other photovoltaic cell adapted to convert solar energy into electricity. The titania device may alternatively be utilized in photoelectrolysis to produce hydrogen from water and sunlight. Because the substrate can include a flexible material, the titania device is well suited for high-throughput production methods for titania, including, for example, roll-to-roll processing techniques.

The present invention provides an effective method of fabricating titania structures on flexible, optionally polymeric, substrates (and other substrates with a relatively low upper operating temperature) while also tailoring the band gap and/or phase of the titania structure as desired. The method of the present invention is relatively inexpensive and permits the use of flexible substrates that might otherwise be damaged by energy or heat from conventional band gap shift or phase transformation methods. In addition, the use of flexible substrates can greatly reduce the solar cell weight and can eliminate the cost and complexity of prior art methods of fabricating titania photovoltaic materials.

These and other features and advantages of the present invention will become apparent from the following description of the invention, when viewed in accordance with the accompanying drawings and appended claims.

### BRIEF DESCRIPTION OF THE DRAWINGS

FIG. 1 is a perspective view a solar cell in accordance with the present invention.

FIG. 2 is a flow-chart illustrating pulsed thermal processing according an embodiment of the present invention.

FIG. 3 is a flow-chart illustrating laser interference treatment according to another embodiment of the present invention.

FIG. 4 is an x-ray diffraction pattern of a titania structure subject to conventional thermal processing.

FIG. 5 is an x-ray diffraction pattern of an anatase titania structure exposed to pulsed thermal processing.

FIG. 6 is an x-ray diffraction pattern of a rutile titania structure exposed to laser interference treatment.

FIG. 7 is a cross-section transmission electron microscopy image of a titania film prior to a laser interference treatment.

FIG. 8 is a cross-section transmission electron microscopy image of a titania film subsequent to a laser interference treatment.

FIG. 9 is an x-ray diffraction pattern illustrating a phase transformation from rutile titania to anatase titania.

### DETAILED DESCRIPTION OF THE CURRENT EMBODIMENT

The invention as contemplated and disclosed herein can greatly improve the processing of titania structures for photovoltaics and photoelectrolysis. In particular, the present invention includes a process using intense pulses of radiant or laser energy to achieve bandgap shift and phase transformation of titania structures on flexible substrates for solar absorption.

### I. BANDGAP SHIFT

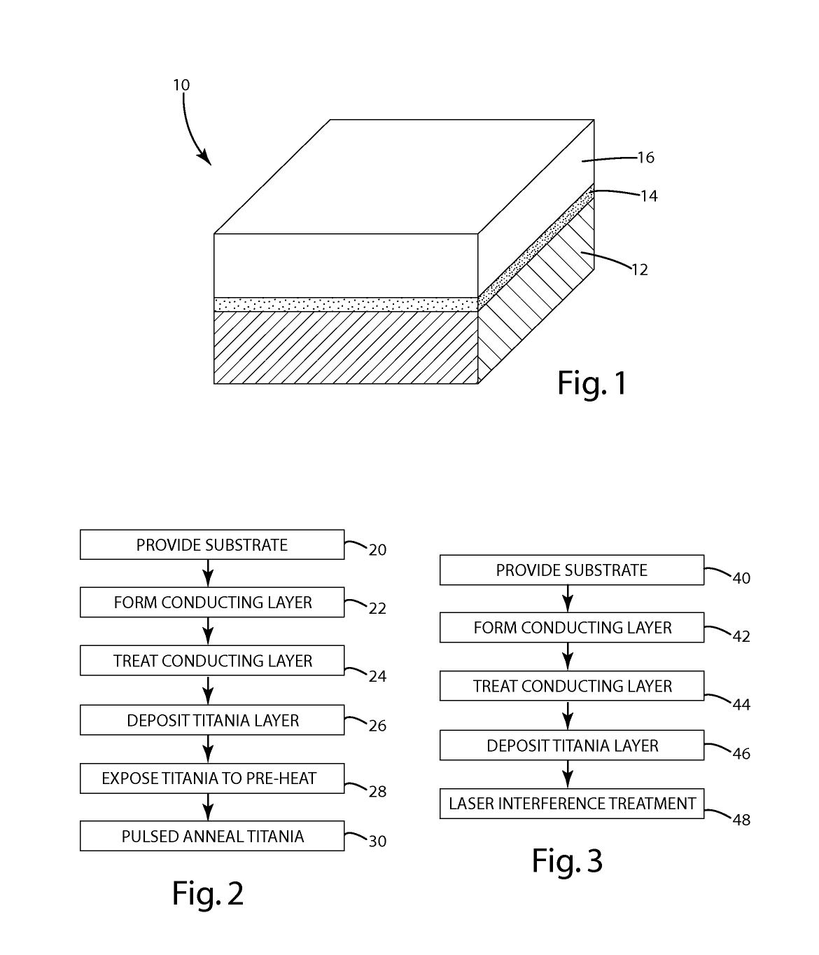

FIG. 1 shows a partial cross-section of one example of a photovoltaic cell 10 manufactured in accordance of the present invention. The photovoltaic cell 10 of the present invention can form part of a solid-state semiconductor solar cell, a dye-sensitized solar cell, or any other photovoltaic cell adapted to convert solar energy into electricity. The photovoltaic cell 10 may alternatively be utilized in photoelectrolysis to produce hydrogen from water and sunlight. The photovoltaic cell 10 may be fabricated in sheets of a size appropriate for its intended use. It may also be fabricated on small substrates or in configurations other than sheets. For example, the photovoltaic cell 10 may be fabricated as a small solar cell for a hand-held electronic device or on large sheets to be applied to large areas such as windows, vehicles or buildings.

Referring now to FIG. 1, the photovoltaic cell includes a flexible substrate 12, a conducting layer 14, and a titania layer 16. The flexible substrate 12 can include one or more substantially planar or substantially non-planar surfaces, optionally being formed from a polymeric material such as polyimide or polycarbonate. Other optional materials include, but are not limited to, polyacetal, polybutylene terephthalate, fluoroplastic, polyphenylene ether, polyethylene terephthalate, polyphenylene sulfide, polyester elastomer, polysulfone, polyether ether ketone, polyether imide, and polyamide imide, or combinations thereof. The conducting layer 14 can include a metalized layer of molybdenum (Mo), tantalum (Ta), tungsten (W) and titanium (Ti), other suitable materials, or combinations thereof. Alternatively, or in addition, the conducting layer 14 can include a transparent conducting oxide, such as zinc oxide (ZnO) or indium tin oxide (ITO), for example. In addition, the conducting layer 14 may be a single layer or multiple layers as desired for the particular application.

The titania layer 16 can be predominantly anatase crystalline (e.g., greater than 50% anatase titania) phase being photoactive in the visible spectrum. The titania layer 16 can be deposited according to any suitable technique, including sputtering, sol-gel, vapor deposition, thermal spraying, cold spraying, or electrochemical anodization of titanium, for example. In addition, the titania layer 16 can optionally be secured to the underlying substrate 12 (or electrode layer 14) via a suitable binder (not shown), including, for example, polyvinyl alcohol. As noted above, the titania layer 16 can be predominately photoactive in the visible spectrum, having a bandgap of approximately 2.4 eV to correspond to the peak of the solar spectrum. In order to achieve the desired bandgap, the titania layer 16 can be subject to pulsed photonic processing with minimal or no thermal effect to the underlying substrate 12. That is, the superficial region of the titania layer 16 opposite the substrate 12 can be exposed to high-intensity pulses of energy, while the downward diffusion of heat from the superficial region of the titania layer 16 toward the underlying substrate 12 is limited due to the short pulse duration of the photonic processing.

One example of photonic processing includes “pulsed thermal processing” using a high intensity arc lamp, and is generally described in connection with the flow-chart of FIG. 2. While FIG. 2 shows a specific embodiment of pulsed thermal processing, it is not intended to be the only manner in which a titania photovoltaic cell 10 may be fabricated. Referring now to step 20, a suitable substrate 12 is provided upon which a photovoltaic device may be fabricated. The substrate 12 may include a flexible or a rigid material. For example, flexible substrates such as polyimide and polycarbonate may be utilized. Rigid substrates such as glass, crystal, acrylic or ceramic may also be utilized. At step 22, a conducting layer 14 is formed on the substrate 12. As noted above, the conducting layer 14 can include a metalized layer (e.g., Mo, Ta, W or Ti, or combinations thereof), or a transparent conducting oxide, such as zinc oxide (ZnO) or indium tin oxide (ITO). The conducting layer 14 can be deposited according to any suitable method. In the present embodiment, a conducting layer 14 of indium tin oxide is deposited by chemical vapor deposition, though other suitable application techniques can also be utilized. At step 24, the conductive layer 14 is optionally treated or cleaned using any of a variety of techniques, including metal etching or laser scanning, for example. At step 26, a contiguous thin film of titania 16 is deposited on the conducting layer 14 and substrate 12. The titania layer 16 is anatase phase in the present embodiment, but can include rutile titania and/or amorphous titania. The titania layer 16 can be deposited via any suitable method, including sputtering, sol-gel, vapor deposition, thermal spraying, cold spraying, or electrochemical anodization of titanium, for example. Alternatively, the titania layer 16 can simply include a wafer cut from an anatase or a rutile wafer. In the present embodiment, the titanium layer 16 generally includes anatase titania having a bandgap of approximately 3.0-3.2 eV, corresponding to the ultraviolet portion of the solar spectrum.

At step 28, a directed plasma arc is provided to pulse anneal the titania device. One suitable directed plasma arc is described in U.S. Pat. No. 4,937,490 to Camm et al and U.S. Pat. No. 7,220,936 to Ott et al, which are hereby incorporated by reference in their entirety. The directed plasma arc can provide power densities of about 20,000 W/cm² or less over areas in excess of 300 cm², though alternative sources of pulsed energy having power densities greater than about 20,000 W/cm² can also be utilized. Referring again to step 28, the titania layer 16 is subject to a single 50 A “pre-heat” pulse from the directed plasma arc from a standoff distance of 2.5 cm for approximately one second, corresponding to an intensity (or more accurately, power flux) of about 65 W/cm². It should be noted however that the pre-heat pulse can include a series of pulses as desired, and can vary in intensity and/or duration.

At step 30, the titania layer 16 is exposed to one or more pulses from the directed plasma arc to rapidly anneal the titania layer 16 without substantially damaging the underlying substrate 12. Energy from the directed plasma arc can be applied as a single pulse, or as a series of pulses in a pulse sequence. Generally, the pulse or pulse sequence will include a pulse duration, a pulse intensity (or power flux), and a pulse periodicity (if a pulse sequence). These parameters may vary from application to application depending on a number of factors, including the desired shift in band gap, the thickness and upper operating temperature of the substrate 12, and the proximity of the directed plasma arc to the titania layer 16. In the present embodiment, for example, the pulse duration can be within the range of 0.1 nanoseconds and 10 seconds, inclusive, optionally between 8-12 nanoseconds. In other embodiments the pulse duration can vary outside this range. The pulse intensity or power flux can be within the range of 0.1 kW/cm² to 20 kW/cm², while in other embodiments the pulse intensity can vary outside this range. The pulse periodicity—defined as the time period between the end of one pulse and the beginning of the next pulse—can vary as desired to permit the temperature of the substrate and/or titania layer to cool to a predetermined temperature (e.g., room temperature) before application of a subsequent pulse. For example, the periodicity can include a lower limit of approximately 100 nanoseconds, with no practical upper limit. Alternatively, the periodicity can vary within the range of 20 microseconds and 2 seconds, while in other embodiments the periodicity can vary beyond this range. A suitable pulse sequence for rapidly annealing a titania layer according to the present invention can include a 400 A pulse, a 500 A pulse, and a 600 A pulse, each pulse having a pulse duration of 100 milliseconds and a periodicity of 100 nanoseconds.

According to the above process, optionally only the superficial region of the titania layer 16 is exposed to these high-intensity pulses of energy, while the downward diffusion of heat from the superficial region of the titania layer 16, and toward the underlying substrate 12, is limited due to the short pulse duration. It should also be noted that the pulse duration, pulse intensity and pulse periodicity can each be held to a single duration throughout a pulsed thermal annealing process, or they can be varied as desired. Throughout the above process, the temperature of the substrate can remain at levels sufficient to limit or prevent melting and/or warping of the polymeric substrate. For example, the temperature of the substrate can remain below 200° C., optionally as low as 130° C., to thereby permit use of flexible, polymeric substrates. Throughout the pre-heat and pulsed thermal processing of steps 28 and 30, the directed plasma arc can include a fixed standoff distance from the upper surface of the titania layer 16. For example, the standoff distance can be 2.5 cm, though other distances can also be utilized, including but not limited to a 2 cm or a 1 cm standoff distance. In addition, the standoff distance can vary throughout a pulsed thermal processing of titania as desired.

According to another aspect of the invention, photonic processing includes “interference treatment” using a high power laser. In particular, a laser can be suitably adapted to process the titania layer 16 into the desired bandgap. The laser can include a excimer laser, a semiconductor laser, a gas laser, a solid-state laser, a chemical laser, or any other suitable laser. According to the present embodiment, the laser heats the superficial region of the titania layer 16 for a relatively short period, wherein the underlying substrate 12 is not subject to the high temperatures to which the titania layer 16 is subjected. The temperature of the substrate can remain at levels sufficient to limit or prevent melting and/or warping of the polymeric substrate. For example, throughout the laser interference treatment the temperature of the substrate can remain below 200° C., optionally as low as 130° C. Therefore, the substrate 12 may be formed of materials having a low melting point, such as polymeric materials.

FIG. 3 shows a flow diagram of one method of laser interference treatment according to the present invention. The laser interference treatment generally described in connection with FIG. 3 was found to convert the bandgap of an ablated spin coated titania layer from 355 nm (corresponding to UV light) to 550 nm (corresponding to visible light). In addition, the laser interference process generally described in connection with FIG. 3 was found to convert the bandgap of a treated spin coated titania layer from 266 nm (corresponding to UV light) to 550 nm (corresponding to visible light). While FIG. 3 shows a specific embodiment of laser interference treatment, it is not intended that this is the only manner in which a titania photovoltaic cell 10 may be treated by laser interference.

Referring now to the flow diagram of FIG. 3, steps 40, 42, 44 and 46 generally correspond to steps 20, 22, 24 and 26 of the flow diagram of FIG. 2. That is, step 40 includes providing a suitable substrate 12, step 42 includes optionally applying a conducting layer 42 on the substrate 12, step 44 includes optionally treating the conducting layer 12 for application of a layer of titania, and step 46 includes depositing a titania precursor or layer 16 on the conductive layer 14 and the substrate 12. At step 48, the titania precursor 16 is subject to one or more pulses of high intensity of infrared energy. The particular pulse sequence at step 48 can vary from application to application as desired. The pulse sequence may vary depending on a number of factors, including the desired shift in band gap, the thickness of the substrate 12, and the proximity of the laser to the titania layer 16. In the present embodiment, the titania precursor 16 is subject to ten pulses of high intensity infrared energy, each pulse having a 2.5 ns pulse width. In the processing of the titania layer 12 at step 48, optionally only the superficial region of the titania layer 16 is exposed to high-intensity pulses of energy, while the downward diffusion of heat from the superficial region of the titania layer 16 is limited due to the short pulse duration. The laser can include an energy density (or energy flux) of approximately 330 mJ/cm², with a pulse duration of 2.5 nanoseconds, and a periodicity of 550 ns. The pulse duration, energy density, and periodicity can be held to a single duration throughout an interference treatment, or it can be varied as desired within a defined range. Similar to the pulsed thermal processing noted above, the high-temperature and short exposure time of the laser interference treatment can assist in grain boundary refinement and grain growth in titania to achieve the bandgap shift in titania.

The resulting anatase titania layer, whether subject to pulsed thermal processing or laser interference treatment, can be photoactive in the visible spectrum, and can be suitably adapted to form part of a solid-state semiconductor solar cell, a dye-sensitized solar cell, or any other photovoltaic cell adapted to convert solar energy into electricity. For example, known titania dye-sensitized solar cells typically include a dye to generate free electrons in response to incident visible light. As one of ordinary skill in the art will readily appreciate, the present invention can greatly reduce or eliminate the need for a sensitizing dye in dye-sensitized solar cells. In addition, the present invention may be performed using roll-to-roll processing. Using this technique, large area sheets of photovoltaic cells may be formed on a continuous web of flexible substrate. The photonic processing steps can be performed between rolls of a roll-to-roll assembly. For example, a directed plasma arc can flash anneal up to a 300 cm² region of the web. Alternatively, multiple lasers may provide interference treatment of the web to increase the rate of processing over large surface areas.

Further, the above disclosed photonic processes may also utilize a feedback control system to adjust a characteristic of the infrared pulse or the laser pulse, optionally in response to the temperature of the substrate. For example, the characteristic can include pulse duration, periodicity, peak wavelength, intensity, or the distance separating the source of the photonic energy and the titania layer. It should also be noted that bandgap shift of crystalline titania can further refined (e.g., shifted, narrowed or broadened) or reversed by subjecting the same to stress. For example, the bandgap of anatase titania described above in connection with FIGS. 1-3 can be reversibly changed by subjecting the titania layer 16 to compressive and/or tensile stress. The resulting change in the crystalline lattice structure can be controlled according any suitable method for inducing bandgap shift in semiconductor materials.

### II. PHASE TRANSFORMATION

The photonic processing of the present invention can also facilitate phase transformation of a titania device. As is known in the art, non-amorphous titania exhibits a crystalline structure of the anatase or the rutile phase. Anatase is the low temperature form of crystalline titania, and rutile is the higher density, high temperature polymorph of crystalline titania.

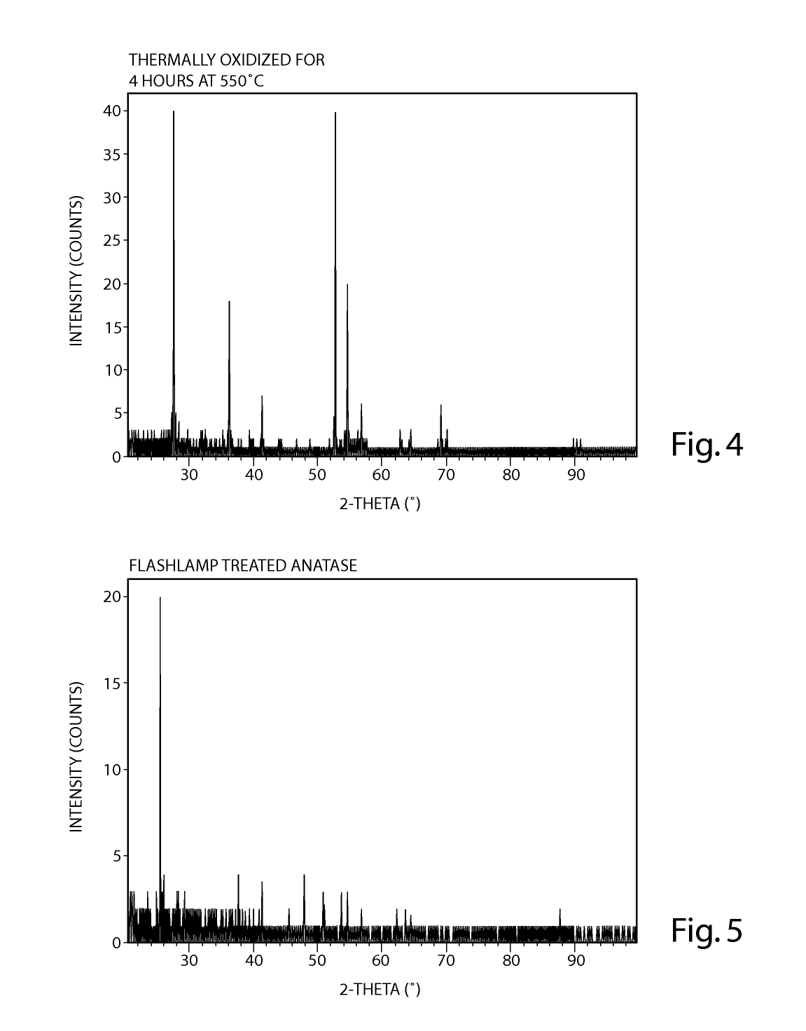

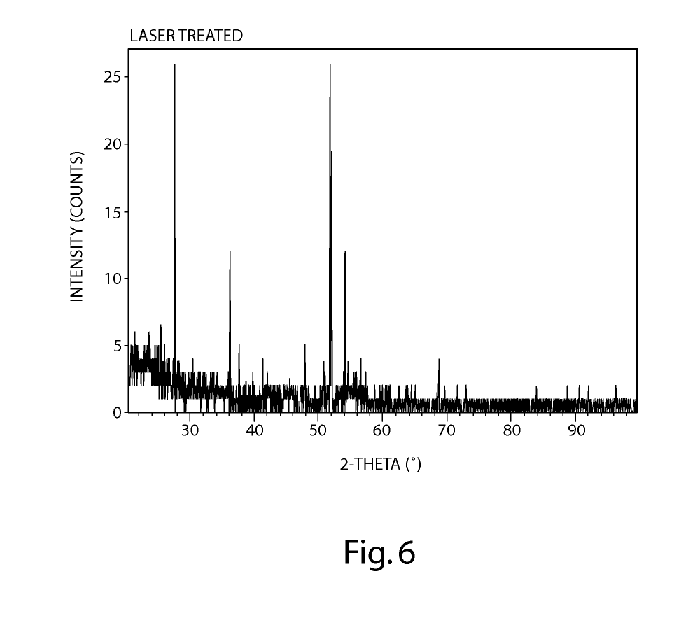

FIGS. 4-6 show the XRD patterns of initially amorphous titania samples thermally oxidized for four hours at 550° C. (FIG. 4), pulse annealed (FIG. 5), or laser treated (FIG. 6). The main peaks in the region 2θ(27.8) and 2θ(28.8) are attributed to anatase titania and rutile titania, respectively. Beginning with FIG. 4, the resulting sample is completely rutile, owing to the conventional calcination at 550° C. for four hours. As noted above however, the conventional heat treatment of titania can severely damage both the supporting substrate and the substrate-titania interface, owing in part to the relatively large coefficient of expansion in many flexible (e.g., polymeric) substrates. Turning now to FIG. 5, the pulse annealed sample—generally treated according to the process described above in connection with FIG. 2—reveals a mixed phase of anatase and rutile, with the predominant phase being anatase. As shown in FIG. 6, the laser treated sample—generally treated according to the process described above in connection with FIG. 3—revealed rutile as the dominant phase of titania.

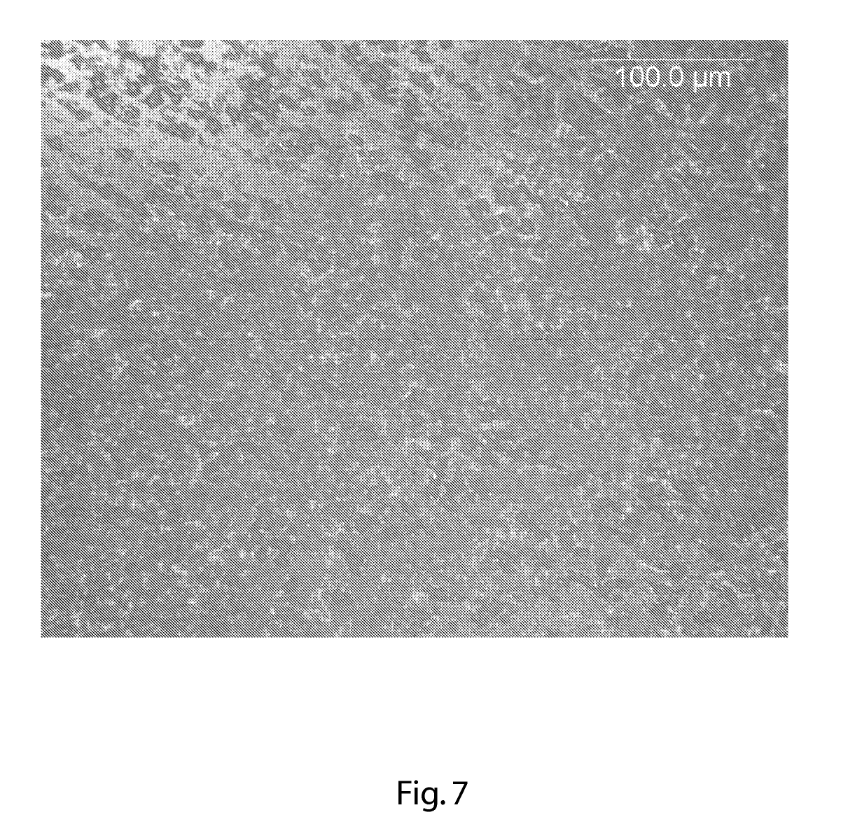

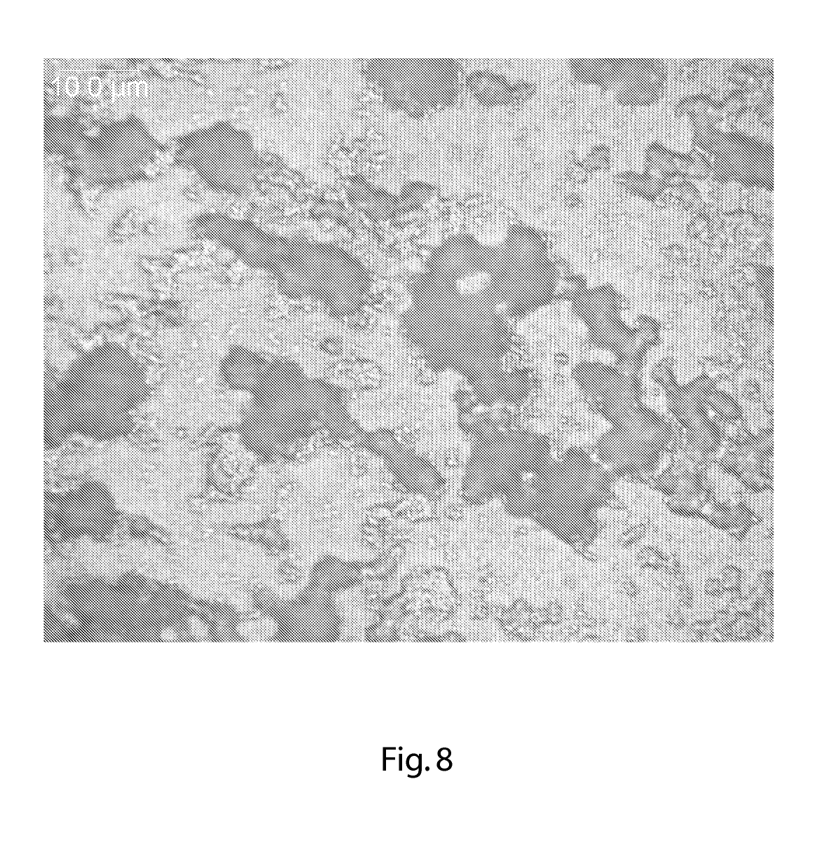

FIG. 7 illustrates a cross-section electron microscopy image of an amorphous titania thin film from an experiment performed prior to periodic laser interference processing, while FIG. 8 illustrates a cross-section electron microscopy image of a rutile titania thin film subsequent to periodic laser interference processing. The grain growth can be readily observed, revealing phase transformation from amorphous to rutile titania over the course of laser interference treatment. In the present example, the laser interference treatment included multiple 2.5 nanoseconds pulses from a laser having an energy density of approximately 330 mJ/cm². Because only the superficial region of the amorphous titania is exposed to high-intensity pulses of energy, the downward diffusion of heat within the amorphous titania layer is limited to thereby minimize any damage to an underlying substrate.

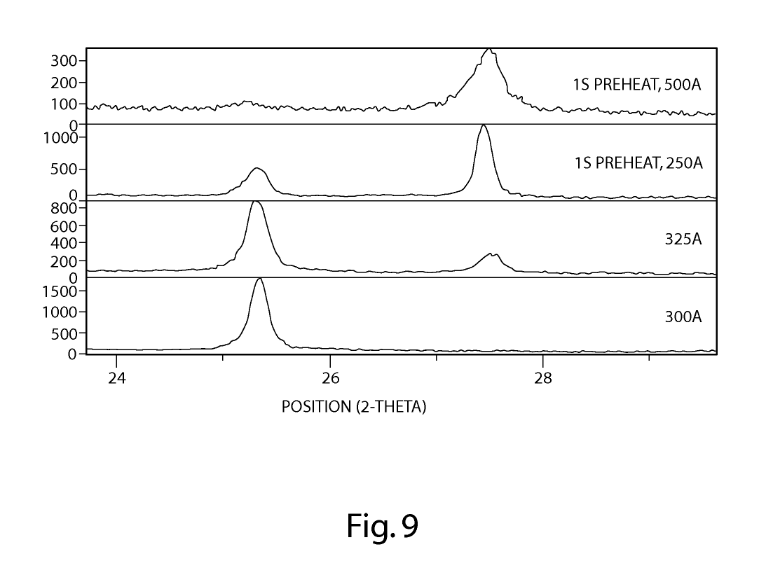

As noted above, pulse thermal processing and laser interference treatment of the present invention can achieve a phase transformation of amorphous titania to crystalline titania of predominantly anatase phase, rutile phase, or a mixed crystalline phase. It should also be noted that pulsed thermal processing and/or laser interference treatment can achieve a phase transformation from anatase titania to rutile titania, and vice versa. For example, FIG. 9 shows the XRD patterns of titania undergoing a phase transformation from rutile titania to anatase titania. The main diffraction peaks in the region 2θ(25.4) and 2θ(27.6) are attributed to anatase titania and rutile titania, respectively. Beginning with the upper portion of FIG. 9, rutile phase is the clear dominant phase of the titania sample after exposure to a is preheat pulse of high intensity thermal radiation at 500 A, corresponding to an intensity or power flux of about 440 W/cm² for a 2.5 cm standoff distance. A second 1 s preheat pulse, but at 250 A, corresponding to an intensity or power flux of about 175 W/cm², achieves a change in the crystalline structure of titania. The phase constitution of titania after this second preheat pulse reveals a mixed crystalline phase of both anatase and rutile titania, with rutile remaining the dominant phase. A 10 ns pulse at 325 A corresponding to an intensity or power flux of about 270 W/cm² achieves a further change in the crystalline structure of titania, wherein anatase becomes the dominant phase. After a 10 ns pulse at 300 A corresponding to an intensity or power flux of about 240 W/cm², the titania sample is (nearly) completely anatase. With the application of each high intensity pulse, the diffraction peak for anatase titania grows stronger and narrower, while the diffraction peak for rutile titania grows weaker and wider.

### III. CONCLUSION

In sum, the photonic processing of the present invention can achieve the following: 1) bandgap shift for titania of the anatase and rutile phase; 2) phase transformation from amorphous titania into crystalline titania; and 3) phase transformation between crystalline titania polymorphs (e.g., anatase to rutile and vice versa). In each of the above disclosed methods of photonic processing, the supporting substrate can remain at temperatures below 200° C., typically at temperatures as low as 130° C., preventing substantial damage to the substrate. The above disclosed methods are also well suited for high-throughput production methods for titania, including, for example, roll-to-roll processing techniques.

The above description is that of current embodiments of the invention. Various alterations and changes can be made without departing from the spirit and broader aspects of the invention as defined in the appended claims, which are to be interpreted in accordance with the principles of patent law including the doctrine of equivalents. Any reference to elements in the singular, for example, using the articles “a,” “an,” “the,” or “said,” is not to be construed as limiting the element to the singular.

1. A laminated article comprising:
a flexible substrate; and
a TiO₂ layer supported by the substrate, the TiO₂ being predominantly anatase crystalline phase.

2. The laminated article according to claim 1 wherein the flexible substrate is formed from a polymeric material.

3. The laminated article of claim 1 wherein the TiO₂ layer includes a bandgap between its valence band and its conduction band between 2.0 eV and 3.0 eV.

4. The laminated article of claim 1 wherein the TiO₂ layer includes a bandgap between its valence band and its conduction band of approximately 2.4 eV.

5. The laminated article according to claim 1 further including a conducting layer disposed between the TiO₂ layer and the flexible substrate.

6. The laminated article according to claim 1 wherein the TiO₂ layer is formed with exposure to at least one pulse of energy from an infrared flashlamp of sufficient energy density and for a sufficient time to crystallize the TiO₂ layer to the predominantly anatase crystalline phase.

7. The laminated article according to claim 6 wherein the infrared flashlamp provides a power output of about 20,000 W/cm².

8. The laminated article according to claim 1 wherein the TiO₂ layer is formed with exposure to at least one pulse of energy from a laser of sufficient energy density and for a sufficient time to crystallize the TiO₂ layer to the predominantly anatase crystalline phase.

9. The laminated article according to claim 8 wherein the laser includes an energy density of approximately 330 mJ/cm².

10. A method of making a flexible article comprising:
providing a flexible substrate;
depositing a TiO₂ film over the substrate; and
exposing the TiO₂ film to a plurality of pulses of energy from an infrared flashlamp of sufficient energy density and for a sufficient time to crystallize the TiO₂ film to predominantly anatase crystalline phase.

11. The method according to claim 10 wherein the annealing step achieves a bandgap shift from greater than 3.0 eV to between 2.0 eV and 3.0 eV.

12. The method according to claim 10 wherein the annealing step achieves a bandgap shift from greater than 3.0 eV to approximately 2.4 eV.

13. The method according to claim 10 wherein the exposing step includes exposing the TiO₂ film to at least two pulses of primarily infrared radiation, the at least two pulses having a duration of no more than 10 s.

14. The method according to claim 10 wherein the exposing step includes exposing the TiO₂ film to at least two pulses of primarily infrared radiation, each pulse having a duration of approximately 100 ms.

15. The method according to claim 10 wherein the flexible substrate is formed from a polymeric material.

16. The method according to claim 10 wherein the temperature of the flexible substrate remains below 200° C. during the exposing step.

17. A method of fabricating a photovoltaic device comprising:
providing a flexible substrate defining an upper operating temperature;
forming a titania layer onto the substrate; and
exposing the titania layer to energy at a sufficient intensity and for a sufficient time to produce a bandgap shift or to cause a change in the phase constitution of the titania layer without causing the substrate to exceed the substrate upper operating temperature.

18. The method according to claim 17 wherein the substrate is formed of a polymeric material having an upper operating temperature of about 400° C. or less.

19. The method according to claim 17 wherein the energy is provided by one of a laser and an infrared flashlamp.

20. The method according to claim 17 wherein the change in the phase constitution of the titania layer includes a change from rutile titania to anatase titania or from anatase titania to rutile titania.

21. The method according to claim 17 wherein:
the titania layer includes a bandgap greater than 3.0 eV; and
the exposing step achieves a bandgap shift from greater than 3.0 eV to approximately 2.4 eV.

22. The method according to claim 17 wherein the temperature of the substrate remains below 200° C. during the exposing step.

23. The method according to claim 17 further including incorporating the device into at least one of a solar cell and a photocatalyst.

24. The method according to claim 17 wherein the titania is one of directly and indirectly supported by the substrate in response to the forming step.
